(19) United States
(12) Patent Application Publication
(10) Pub. No.: US 2023/0223911 A1
(43) Pub. Date: Jul. 13, 2023

(54) ACOUSTIC WAVE DEVICE AND METHOD FOR PRODUCING SAME

(71) Applicant: Sanan Japan Technology Corporation, Tokyo (JP)

(72) Inventors: Kanehisa Kimbara, Tokyo (JP); Shinichi Shioi, Tokyo (JP)

(73) Assignee: Sanan Japan Technology Corporation, Tokyo (JP)

(21) Appl. No.: 18/152,629

(22) Filed: Jan. 10, 2023

(30) Foreign Application Priority Data
Jan. 12, 2022 (JP) 2022-003142

(51) Int. Cl. H03H 3/08; H03H 9/05; H03H 9/10

(52) U.S. Cl. CPC H03H 3/08; H03H 9/059; H03H 9/1064

(57) ABSTRACT

An acoustic wave device includes: a wiring substrate; a device chip mounted on the wiring substrate; a photocurable resin film disposed so as to surround an air gap between the wiring substrate and the device chip; a ceramics layer formed so as to cover the photocurable resin film; and a sealing portion covering the ceramics layer.

### CROSS-REFERENCE TO RELATED APPLICATION(S)

This application claims priority to Japanese Application No. 2022-003142, filed Jan. 12, 2022, which are incorporated herein by reference, in their entirety, for any purpose.

### BACKGROUND OF THE INVENTION

### Field of the Invention

The present disclosure relates to an acoustic wave device and a method for producing the same.

### Description of the Related Art

Patent Document 1 (JP2020-53812) discloses a packaging method of an acoustic wave device. This packaging method includes face-down mounting a chip on a wiring substrate and covering a periphery of the chip with a sealing member made of metal.

For example, Surface Acoustic Wave (SAW) filters need securing heat dissipation in order to prevent the functional elements from being destroyed.

However, when a device chip is covered with a metal layer in order to obtain heat dissipation and shielding effects, stray capacitance is generated.

### SUMMARY OF THE INVENTION

Some examples described herein may address the above-described problems. Some examples described herein may provide an acoustic wave device excellent in heat dissipation property while avoiding generation of stray capacitance.

In some examples, an acoustic wave device includes a wiring substrate, a device chip mounted on the wiring substrate, a photocurable resin film disposed so as to surround an air gap between the wiring substrate and the device chip, a ceramics layer formed so as to cover the photocurable resin film and a sealing portion covering the ceramics layer.

### BRIEF DESCRIPTION OF THE DRAWINGS

FIG. 1 is a cross-sectional view of an acoustic wave device 10 according to an embodiment of the present disclosure;

FIG. 2 is a flowchart showing a method of producing the acoustic wave device;

FIG. 3 shows a UV exposure for curing a part of a resin;

FIG. 4 shows an example of removing the resin;

FIG. 5 shows an example of forming a ceramics layer 20; and

FIG. 6 is a cross-sectional view of a module 100 according to the embodiment 2 of the present invention.

### DETAILED DESCRIPTION

Embodiments will be described with reference to the accompanying drawings. In the drawings, the same or corresponding parts are denoted by the same reference numerals. Duplicate descriptions of such portions may be simplified or omitted.

### EMBODIMENT

### Embodiment 1

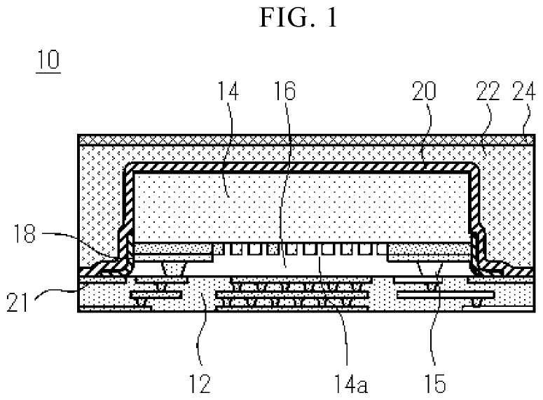

FIG. 1 is a cross-sectional view of an acoustic wave device 10 according to the embodiment 1 of the present disclosure. This acoustic wave device 10 includes a wiring substrate 12. According to an example, the wiring substrate 12 is a Printed Circuit board (PCB) substrate or a High Temperature Co-fired Ceramics (HTCC) substrate.

According to another example, the wiring substrate 12 is a Low Temperature Co-fired Ceramics (LTCC) multilayer substrate made of a plurality of dielectric layers.

According to another example, an arbitrary substrate provided with a base material and wiring electrodes penetrating the base material can be used as the wiring substrate. In the example of FIG. 1, the wiring substrate 12 includes the base material, an upper electrode, and a lower electrode electrically connected to the upper electrode by a via wiring or the like.

A passive component such as a capacitor or an inductor may be formed within the wiring substrate 12.

According to one example, the acoustic wave device 10 includes a device chip 14. The device chip 14 provides the functions such as a bandpass filter, a duplexer, or a dual filter configured by functional elements of a plurality of surface acoustic wave resonators or a plurality of thin film acoustic resonators.

The device chip 14 is mounted on the wiring substrate 12 while facing the first main surface having functional elements to the wiring substrate 12.

In the example of FIG. 1, an Interdigital Transducer (IDT) 14a and a pair of reflectors are provided as the functional element. The IDT 14a and the pair of reflectors are mounted on the first main surface of the device chip 14.

In one example, a wiring pattern may be formed on the first main surface by an appropriate metal or alloy such as silver, aluminum, copper, titanium, or palladium. The IDT 14a and the pair of reflectors are provided to excite surface acoustic waves.

According to another example, the functional elements formed on the first main surface are a receiving filter and a transmitting filter.

The receiving filter is formed so that an electrical signal in a desired frequency band can pass. For example, the receiving filter is a ladder-type filter consisting of a plurality of series resonators and a plurality of parallel resonators.

The transmitting filter is formed so that an electrical signal in a desired frequency band can pass. For example, the transmitting filter is a ladder-type filter consisting of a plurality of series resonators and a plurality of parallel resonators.

The acoustic wave device 14 has a substrate formed of, for example, a piezoelectric single crystal such as lithium tantalate, lithium niobate, or quartz. According to another example, the acoustic wave device 14 has a substrate formed of piezoelectric ceramics.

According to another example, the acoustic wave device 14 has a substrate to which a piezoelectric substrate and a support substrate are bonded. For example, the support substrate may be a substrate formed of sapphire, silicon, alumina, spinel, quartz, or glass.

The device chip 14 is mounted on the wiring substrate 12 by a bump 15.

The bump 15 is, for example, a gold bump. According to another example, the bumps 15 can be replaced by a solder. According to an example, the height of the bumps 15 is between 10 μm and 50 μm.

There is an air gap 16 between the wiring substrate 12 and the device chip 14. The air gap 16 is covered with a photocurable resin 18.

At least a portion of the sidewall of the device chip 14 is covered with the photocurable resin 18. Alternatively, the air gap 16 may be covered with the photocurable resin 18 from the end of the first main surface of the device chip 14 to the wiring substrate 12.

In some embodiments of the disclosure, the photocurable resin 18 may not be formed on at least a part of a non-opposed main surface and a surface in a thickness direction of the wiring substrate 12. For example, as shown in FIG. 1, at least a portion of the sidewall of the device chip 14 may not be covered with the photocurable resin 18.

The photocurable resin 18 is formed curvilinearly from the lower portion of the side wall of the device chip 14 to the wiring substrate 12.

The thickness of the photocurable resin 18 is, for example, 5 μm to 100 μm. Preferably, it is 25 μm to 75 μm. More preferably, the thickness is 35 μm to 55 μm in order to achieve both reliable photocuring in a producing process described later and ensuring sealing of the air gap 16 between the wiring substrate and the functional element.

According to one example, the photocurable resin 18 may include a thermosetting property. The thermosetting property of the resin is one in which the resin is temporarily softened at a first temperature which is higher than an ordinary temperature and is cured by continuing the first temperature or changing the first temperature to a second temperature higher than the first temperature.

Though the photocurable resin 18 is cured with light, may be thermally cured depending on the thermal hysteresis in the producing process of the acoustic wave device 10 or the like.

Examples of the material of the photocurable resin 18 is any one of the following.
Epoxy-based KPM500 dry films manufactured by Nippon Kayaku
Epoxy-based PSR-800 AUS410, PSR-800 AUS SR1 manufactured by Taiyo Ink
Polyimide-based LPA-22 manufactured by Toray Industries

The device chip 14 has a second main surface. The second main surface is a surface opposite to the first main surface.

The second main surface is covered with a ceramics layer 20. For example, aluminum nitride or alumina can be used as the ceramics layer 20.

The ceramics layer 20 can be formed of a material having the thermal conductivity of, for example, 145 to 230 W/m K at an ordinary temperature (25° C.).

This improves the heat dissipation of the device chip 14.

For example, aluminum nitride has the thermal conductivity of 180 to 230 W/m K at an ordinary temperature (25° C.).

As shown in FIG. 1, the upper portion of the sidewall of the device chip 14 is covered with the ceramics layer 20. This further improves the heat dissipation of the device chip 14.

The ceramics layer 20 may have a polycrystalline structure. In addition, the ceramics layer 20 may have a structure in which a crystal grain size is larger in the horizontal direction than in the vertical direction of the second main surface of the device chip 14. This further improves the heat dissipation of the device chip 14.

The ceramics layer 20 may be formed to bite into the photocurable resin 18. In other words, the interface between the ceramics layer 20 and the photocurable resin 18 may have a jagged shape.

As a result, the adhesion between the ceramics layer 20 and the photocurable resin 18 is improved, and the sealing property of the air gap 16 can be improved.

The ceramics layer 20 preferably comes into contact with a metal pattern 12 on the wiring substrate 12. This further improves the heat dissipation of the device chip 14.

As shown in FIG. 1, a sealing portion 22 is formed so as to cover the ceramics layer 20. The sealing portion 22 may be formed of, for example, an insulator such as a synthetic resin, or may be formed of a metal as long as the stray capacitance is not problem.

As the synthetic resin, for example, epoxy resin, polyimide, or the like can be used, but the present invention is not limited thereto. Preferably, an epoxy resin is used to form the sealing portion 22 using a low temperature curing process.

The air gap 16 between the wiring substrate 12 and the device chip 14 is hermetically sealed by the photocurable resin 18, the ceramics layer 20, and the sealing portion 22.

As shown in FIG. 1, a metal layer 24 is formed on the sealing portion 22. By providing the metal layer 24, it is possible to provide the acoustic wave device 10 with an improved shielding effect.

Since the ceramics layer 20 and the sealing portion 22 are formed between the metal layer 24 and the device chip 14, it is possible to avoid a problem of stray capacitance while obtaining a shielding effect. Further, it contributes to further improvement of the heat dissipation property of the metal layer 24.

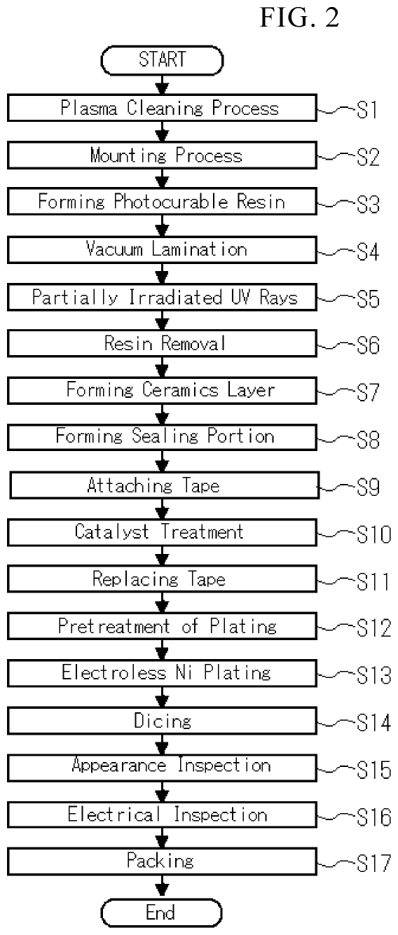

FIG. 2 is a flowchart showing a method of producing the acoustic wave device 10. The method of producing the acoustic wave device 10 of FIG. 1 will be described with reference to the flowchart.

In the step S1, a package substrate is subject to a plasma cleaning process. According to one example, the wiring substrate is a substrate in which a unit wiring substrate 12 is arrayed in a two-dimensional direction. In this case, it can be said that a plurality of the unit wiring substrate 12 are disposed on the wiring substrate.

In a step S2, the device chip 14 is mounted on the wiring substrate with flip-chip bonding.

According to one example, the step S2 is an Au—Au junction (Gold to Gold Interconnection: GGI) process. The plurality of device chips 14 are mounted on the wiring substrate with flip-chip bonding using ultrasonic waves, heating, or pressurization as needed.

Next, the method proceeds to a step S3. The step S3 is a step of forming the photocurable resin 18.

First, in the step S2, a resin sheet is placed so as to cover the plurality of device chips 14 mounted on the wiring substrate. The resin sheet is made of a photocurable resin.

The resin sheet is, for example, a liquid epoxy resin sheet. According to another example, the resin sheet may be a synthetic resin such as polyimide different from an epoxy resin.

In one example, a protective film made of polyethylene terephthalate (PET) can be provided on an upper surface of the resin sheet. In one example, a base film made of polyester can be provided on a lower surface of the resin sheet.

By placing the resin sheet on the plurality of device chips 14, the resin sheet is temporarily fixed to the plurality of device chips 14.

In a step S4, a resin is then provided between the chips by vacuum lamination. According to one example, the resin is provided between the chips by applying pressure to the resin sheet in the direction of the wiring substrate 12 under vacuum.

In one example, a pressure toward the wiring substrate 12 can be applied to the resin sheet by silicon rubber inflated by compressed air. In another example, a rubber plate can be used to apply pressure to the resin sheet in the direction of the package substrate 12.

Resin may be provided between the chips in a different manner than the vacuum lamination.

For example, a method called thermal roller lamination may be employed.

In the thermal roller lamination method, by passing a work between an upper roller and a lower roller heated to at least the softening temperature of the resin sheet, the resin sheet is provided on the upper surface of the plurality of device chips, the side surface of the plurality of device chips and the upper surface of the wiring substrate 12.

The resin sheet in this case has the photocuring property and the thermosetting property.

Then, in a step S5, a portion of the resin covering the air gap 16 between the wiring substrate 12 and the device chip 14 is cured by light.

FIG. 3 is a view showing curing a portion of the resin covering the air gap 16 between the wiring substrate 12 and the device chip 14.

As shown in FIG. 3, the portion of the resin covering the air gap 16 between the wiring substrate 12 and the device chip 14 is irradiated with UV rays.

According to one example, in this UV irradiation, UV rays emitted from UV irradiation device is provided only in the portion covering the gap 16 between the wiring substrate 12 and the device chip 14, and in a neighboring area thereof, in a part of the sidewall of the device chip 14 and in a part of the wiring substrate 12. The other portion of the resin is not UV irradiated.

Further, in UV irradiation, it is desirable that the irradiation be performed non-vertically to the surface of the printed wiring substrate.

In addition, it is desirable to irradiate along the corner portion formed by the wiring substrate and the device chip 14.

The irradiation may be selectively performed by scanning the stage holding the wiring substrate while moving, or a mask may be used in combination.

This is because, in each of the four sides of the plurality of device chips 14 arranged in an array before singulation (in a case where the device chips are substantially rectangular parallelepiped), the portion covering the air gap 16 of the photocurable resin 18 and the adjacent region thereof can be selectively photocured.

The process of selectively curing the photocurable resin 18 is not limited to UV irradiation. For example, the portion covering the air gap 16 may be selectively cured by selectively irradiating the electron beam.

By curing the portion of the photocurable resin 18 covering the air gap 16 and its adjacent region and maintaining the same shape as the photocurable resin 18 of FIG. 1, it is possible to avoid the adhesion of debris such as ceramic particles to the functional element of the acoustic wave device 10 in a subsequent step.

According to an example, this air gap 16 is an enclosed space.

Next, the method proceeds to a step S6. In the step S6, the portion of the resin is removed.

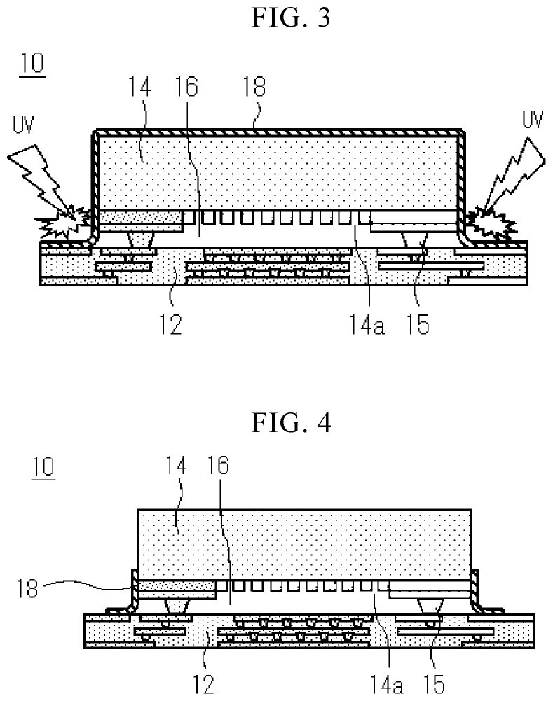

FIG. 4 shows an example of removing the resin. In this example, resins other than the portion of the photocurable resin 18 covering the air gap 16 and the adjacent region thereof are removed. According to an example, the resin is removed by developing.

Next, the method proceeds to a step S7. In the step S7, the ceramics layer 20 are formed.

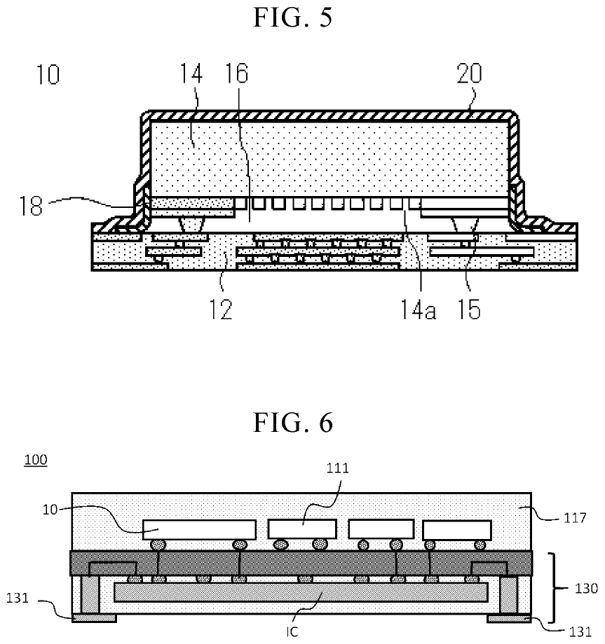

FIG. 5 shows an example of forming the ceramics layer 20. In this example, an aluminum nitride layer is formed over the wiring substrate 12, the device chip 14, and the photocurable resin 18. Also, the aluminum nitride layer is formed in a partial region of the side wall of the device chip 14.

The aluminum nitride layer can be formed by the aerosol deposition method. The aluminum nitride is preliminarily formed into fine particles or ultrafine particles and mixed with gas to be aerosolized. This is injected to the wiring substrate on which the plurality of device chips 14 is arrayed by accelerating with gas conveyance.

The injection angle can be set to be perpendicular and non-perpendicular to the plane direction of the wiring substrate in the film forming process by the aerosol deposition method. By selecting non-perpendicular injection angle to the upper surface of the device chip 14, the ceramic particles that have collided with the surface of the device chip 14 or the deposited ceramic particles are plastically deformed, and the ceramic layer 20 can have a structure in which the crystal grain size is larger in the horizontal direction than in the vertical direction of the second main surface of the device chip 14.

As a result, the ceramic layer 20 can be formed by a low-temperature process, and the breakage of the acoustic wave device 10 in the producing process can be suppressed. When the ceramic layer 20 is amorphous, the thermal conductivity is deteriorated, and when heating is performed to grow the grain size, the acoustic wave device 10 is easily destroyed.

Further, the injection angle can be made non-perpendicular to the planar direction of the wiring substrate with respect to the side wall of the device chip 14 and the portion of the photocurable resin 18 covering the air gap 16.

As a result, the film can be efficiently formed on the side wall of the device chip 14 and the portion of the photocurable resin 18 covering the air gap 16

Regarding the aerosol deposition method, there is a problem that a part of the injected particles may be scattered and destroy the functional element formed on the first main surface of the device chip 14.

However, according to the present invention, since the photocurable resin 18 covers the gap 16, the ceramic layer 20 can be formed on the device chip 14 by the aerosol deposition method without destroying the functional element.

Next, the process proceeds to step S8. In the step S8, the sealing portion 22 is formed. An epoxy resin is used to form the sealing portion 22 using a low temperature curing process.

Next, in the step S9, a tape is attached to the back surface of the wiring substrate 12. Subsequently, in a step S10, a catalyst treatment for causing an electroless plating reaction is performed.

Then, the tape is replaced in a step S11, a pretreatment is performed in a step S12, an electroless Ni plating is formed in a step S13. Thus, the metal layer 24 covering the sealing portion 22 is formed by plating.

The metal layers 24 may be formed by a method other than electroless Ni plating.

According to one example, in order to form the metal layer, an electroless Cu plating and an electroless Ni plating are conducted in this order. According to another example, a silver coating and an electroless Ni plating are conducted in this order to form the metal layer.

According to yet another example, Ti formation, Cu sputtering, electrolytic Ni plating are conducted in this order to form the metal layer. In these modified examples, the adhesiveness between the resin and the metal layer can be enhanced as compared with the case where the metal layer is formed by electroless Ni plating.

Next, in the step S14, the wiring substrate 12 is diced. As a result, the singulated acoustic wave device 10 is produced.

Next, the appearance is inspected in a step S15, and the electrical characteristics of the product are inspected in a step S16. If there is no problem, the product is packaged in a step S17. Thus, the manufacture of the acoustic wave device 10 shown in FIG. 1 is completed.

Some examples described herein may provide an acoustic wave device excellent in heat dissipation property while avoiding generation of stray capacitance.

### Embodiment 2

Next, Embodiment 2 which is another embodiment of the present invention will be described. FIG. 6 is a cross-sectional view of a module 100 in the embodiment 2 of the present invention.

As shown in FIG. 6, the acoustic wave device 10 is mounted on the main surface of a wiring substrate 130.

The acoustic wave device 10 may be, for example, a duplexer employing the configuration described in the embodiment 1.

The wiring substrate 130 has a plurality of external connection terminals 131. The plurality of external connection terminals 131 are mounted on a motherboard of a predetermined mobile communication terminal.

An inductor 111 is mounted on the main surface of the wiring substrate 130 for impedance matching. The inductor 111 may be Integrated Passive Device (IPD).

The module 100 is sealed by a sealing portion 117 for sealing a plurality of electronic components including the acoustic wave device 1.

An integrated circuit component IC is mounted inside the circuit board 130. Although not shown, the integrated circuit component IC includes a switching circuit and a low noise amplifier.

The description of other structures is omitted because it is the same as that of FIG. 1.

Some examples described above may provide a module comprising an acoustic wave device excellent in heat dissipation property while avoiding generation of stray capacitance.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. An acoustic wave device comprising:
a wiring substrate;
a device chip mounted on the wiring substrate;
a photocurable resin film disposed so as to surround an air gap between the wiring substrate and the device chip;
a ceramics layer formed so as to cover the photocurable resin film; and
a sealing portion covering the ceramics layer.

2. The acoustic wave device according to claim 1, wherein the photocurable resin film is not formed on at least a part of a non-opposed main surface and a surface in a thickness direction of the wiring substrate, and is formed in a curved shape in a cross section from a lower end of a surface in a thickness direction of the device chip to the wiring substrate.

3. The acoustic wave device according to claim 1, wherein the photocurable resin film has a thickness of 5 μm to 100 μm.

4. The acoustic wave device according to claim 1, wherein the ceramics layer has a thermal conductivity of 145 to 230 W/m K.

5. The acoustic wave device according to claim 1, wherein the ceramics layer is aluminum nitride or alumina.

6. The acoustic wave device according to claim 1, wherein a metal layer is formed on the sealing portion.

7. A module including the acoustic wave device according to claim 1.

8. A method of producing an acoustic wave device, the method comprising:
a step of mounting a device chip on a wiring substrate;
a step of disposing a photocurable resin film over the device chip;
a step of photocuring a portion of the photocurable resin film;
a step of removing a portion of the photocurable resin film that is not photocured; and
a step of forming a ceramics layer on the wiring substrate, the device chip and the photocurable resin film.

9. The method according to claim 8, wherein the step of photocuring the portion of the photocurable resin film by irradiating light beams non-perpendicularly to a surface direction of the wiring substrate.

10. The method according to claim 8, wherein the step of photocuring the portion of the photocurable resin film comprises irradiating light beams along a portion of a corner formed by the wiring substrate and the device chip.

11. The method according to claim 8, wherein the step of photocuring the portion of the photocurable resin film excludes photocuring the photocurable resin disposed on the non-facing surface of the device chip with respect to the wiring substrate.

12. The method according to claim 8, wherein the step of forming the ceramics layer is executed by an aerosol deposition method.

13. The method according to claim 8, further comprising a step of forming a metal layer on the sealing portion by plating.
